(19) United States
(12) Patent Application Publication
(10) Pub. No.: US 2007/0090507 A1
(43) Pub. Date: Apr. 26, 2007

(54) Multi-chip package structure

(76) Inventors: Chian-Chi Lin, Kaoshiung (TW); Cheng-Yin Lee, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/332,293

(22) Filed: Jan. 17, 2006

(30) Foreign Application Priority Data
Oct. 26, 2005 (TW) 094137530

(51) Int. Cl. H01L 23/02

(52) U.S. Cl. 257/686; 257/778; 257/E23.085

(57) ABSTRACT

A multi-chip package structure includes a first substrate, a first chip, a sub-package, and a first molding compound. The first substrate has a first surface and a second surface. The first chip is attached to the first surface of the first substrate by flip-chip bonding so as to reduce a step of wire bonding and reduce the total height of the package structure. The sub-package includes a second substrate, a second chip, and a second molding compound. The second substrate has a first surface and a second surface. The second substrate is a flexible substrate and is directly connected to the first surface of the first substrate so as to reduce another step of wire bonding.

### BACKGROUND OF THE INVENTION

1. Field of the Invention

The present invention relates to a semiconductor package structure, and more particularly, to a package structure having a sub-package therein.

2. Description of the Related Art

Referring to FIG. 1, a schematic view of a conventional multi-chip package structure as disclosed in U.S. Pat. No. 6,838,761 is shown. The multi-chip package structure 1 comprises a first substrate 11, a first chip 12, a first adhesive 13, a plurality of first connecting wires 14, a first molding compound 15, a sub-package 2, a third adhesive 16, a plurality of third connecting wires 17, a third molding compound 18, a heat spreader 19, and a plurality of solder balls 20. The first substrate 11 has an upper surface 111 and a lower surface 112. The first chip 12 is attached on the upper surface 111 of the first substrate 11 by the first adhesive 13. The first connecting wires 14 are used for electrically connecting the first chip 12 and the upper surface 111 of the first substrate 11. The first molding compound 15 encloses the first chip 12, the first connecting wires 14, and a part of the upper surface 111 of the first substrate 11. The first molding compound 15 has an upper surface 151.

The sub-package 2 comprises a second substrate 21, a second chip 22, a second adhesive 23, a plurality of second connecting wires 24, and a second molding compound 25. The second substrate 21 has an upper surface 211 and a lower surface 212. The second chip 22 is attached on the upper surface 211 of the second substrate 21 by the second adhesive 23. The second connecting wires 24 are used for electrically connecting the second chip 22 and the upper surface 211 of the second substrate 21. The second molding compound 25 encloses a part of the second chip 22, the second connecting wires 24, and a part of the upper surface 211 of the second substrate 21.

The sub-package 2 is stacked on the upper surface 151 of the first molding compound 15. The lower surface 212 of the second substrate 21 is attached on the upper surface 151 of the first molding compound 15 by the third adhesive 16. The second substrate 21 is electrically connected to the upper surface 111 of the first substrate 11 by the third connecting wires 17. The third molding compound 18 encloses the sub-package 2, the first molding compound 15, and the upper surface 111 of the first substrate 11. The heat spreader 19 has a heat spreader body 191 and a support protion 192, wherein the support portion 192 extends outward and downward from the heat spreader body 191, for supporting the heat spreader body 191, and the heat spreader body 191 is exposed outside the third molding compound 18. The solder balls 20 are disposed on the lower surface 112 of the first substrate 11, for connecting an external device.

The disadvantage of the conventional multi-chip package structure 1 is described as follows. The second substrate 21 and the first substrate 11 are electrically connected by the third connecting wires 17, and after the sub-package 2 is attached on the upper surface 151 of the first molding compound 15, the external side of the second substrate 21 is suspended, thus increasing the difficulty of wire-bonding. Moreover, the first chip 12 is electrically connected to the upper surface 111 of the first substrate 11 by the first connecting wires 14. Therefore, the first chip 12 and the first connecting wires 14 are stacked on the sub-package 2 only after being enclosed in the first molding compound 15. As such, a step of molding is needed, and the total height of the package structure 1 is also increased.

Consequently, there is an existing need for a multi-chip package structure to solve the above-mentioned problems.

### SUMMARY OF THE INVENTION

The objective of the present invention is to provide a multi-chip package structure. The multi-chip package structure comprises a first substrate, a first chip, a sub-package, and a first molding compound. The first substrate has a first surface and a second surface. The first chip is attached to the first surface of the first substrate by flip-chip bonding. The sub-package comprises a second substrate, a second chip, and a second molding compound. The second substrate has a first surface and a second surface. The second substrate is a flexible substrate and is connected to the first surface of the first substrate. The second chip is electrically connected to the second substrate. The second molding compound encloses the second chip and a part of the second surface of the second substrate. The first molding compound encloses the first chip, the sub-package, and a part of the first surface of the first substrate. Since the first chip is attached on the first surface of the first substrate by flip-chip bonding, a step of wire bonding can be omitted, and the total height of the package structure can be reduced as well. Moreover, the first substrate and the second substrate are connected directly; therefore, another step of wire bonding can be further omitted.

### BRIEF DESCRIPTION OF THE DRAWINGS

FIG. 1 shows a schematic view of a conventional multi-chip package structure as disclosed in U.S. Pat. No. 6,838,761;

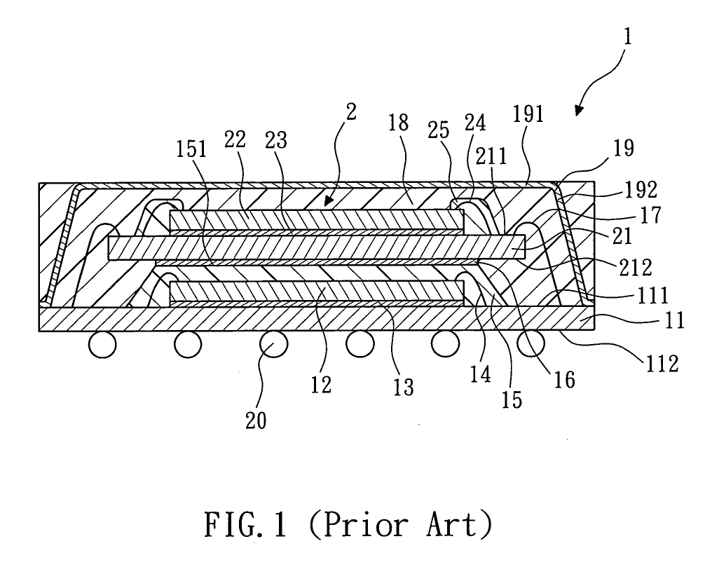

FIG. 2 shows a schematic sectional view of the multi-chip package structure according to a first embodiment of the present invention;

FIGS. 3a -3f show schematic views of a manufacturing process of the first embodiment of FIG. 2;

FIG. 4 shows a schematic sectional view of the multi-chip package structure according to a second embodiment of the present embodiment; and

FIG. 5 shows a schematic sectional view of the multi-chip package structure according to a third embodiment of the present embodiment.

### DETAILED DESCRIPTION OF THE INVENTION

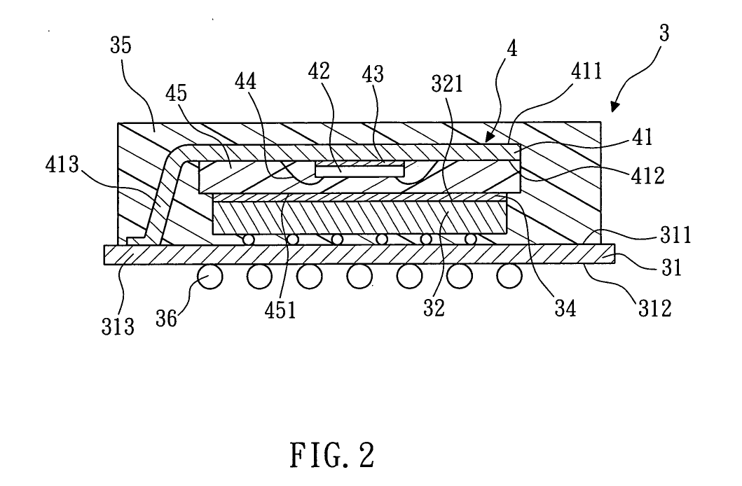

Referring to FIG. 2, a schematic sectional view of the multi-chip package structure according to a first embodiment of the present invention is shown. The multi-chip package structure 3 comprises a first substrate 31, a first chip 32, a sub-package 4, a first adhesive 34, a first molding compound 35, and a plurality of solder balls 36. The first substrate 31 has a first surface 311 (upper surface), a second surface 312 (lower surface), and a first connection end 313. The first chip 32 is attached to the first surface 311 of the first substrate 31 by flip-chip bonding, and has a first surface 321 (upper surface). The first chip 32 may be, but is not limited to, a digital chip, an analog chip, an optical chip, a logic chip, a microprocessing chip, or a memory chip.

The sub-package 4 comprises a second substrate 41, a second chip 42, a second adhesive 43, a plurality of second connecting wires 44, and a second molding compound 45. The second substrate 41 has a first surface 411 (upper surface), a second surface 412 (lower surface), and a second connection end 413. The second chip 42 is attached on the second surface 412 of the second substrate 41 by the second adhesive 43. The second chip 42 may be, but is not limited to, a digital chip, an analog chip, an optical chip, a logic chip, a microprocessing chip, or a memory chip. The second connecting wires 44 are used for electrically connecting the second chip 42 to the second surface 412 of the second substrate 41. The second molding compound 45 encloses a part of the second chip 42, the second connecting wires 44, and a part of the second surface 412 of the second substrate 41. The second molding compound 45 has a second surface 451 (lower surface).

The sub-package 4 is stacked on the first surface 321 of the first chip 32, and the second surface 451 of the second molding compound 45 is attached to the first surface 321 of the first chip 32 by the first adhesive 34. Moreover, the second substrate 41 is a flexible substrate, and the second connection end 413 is connected to the first surface 311 of the first connection end 313 of the first substrate 31. In the embodiment, the first surface 311 of the first connection end 313 of the first substrate 31 has a plurality of first contacts (not shown) thereon, and the second surface 412 of the second connection end 413 of the second substrate 41 has a plurality of second contacts (not shown) thereon. After the second surface 412 of the second connection end 413 of the second substrate 41 directly contacts the first surface 311 of the first connection end 313 of the first substrate 31, the first contacts and the second contacts are electrically connected by hot pressing.

The first molding compound 35 encloses the first chip 32, the sub-package 4, and a part of the first surface 311 of the first substrate 31. The solder balls 36 are formed on the second surface 312 of the first substrate 31, for connecting an external device.

Since the first chip 32 is attached to the first surface 311 of the first substrate 31 by flip-chip bonding, a step of wire bonding can be omitted, and total height of the multi-chip package structure 3 can be reduced as well. Moreover, the first substrate 31 directly contacts the second substrate 41; therefore, another step of wire bonding can be further omitted.

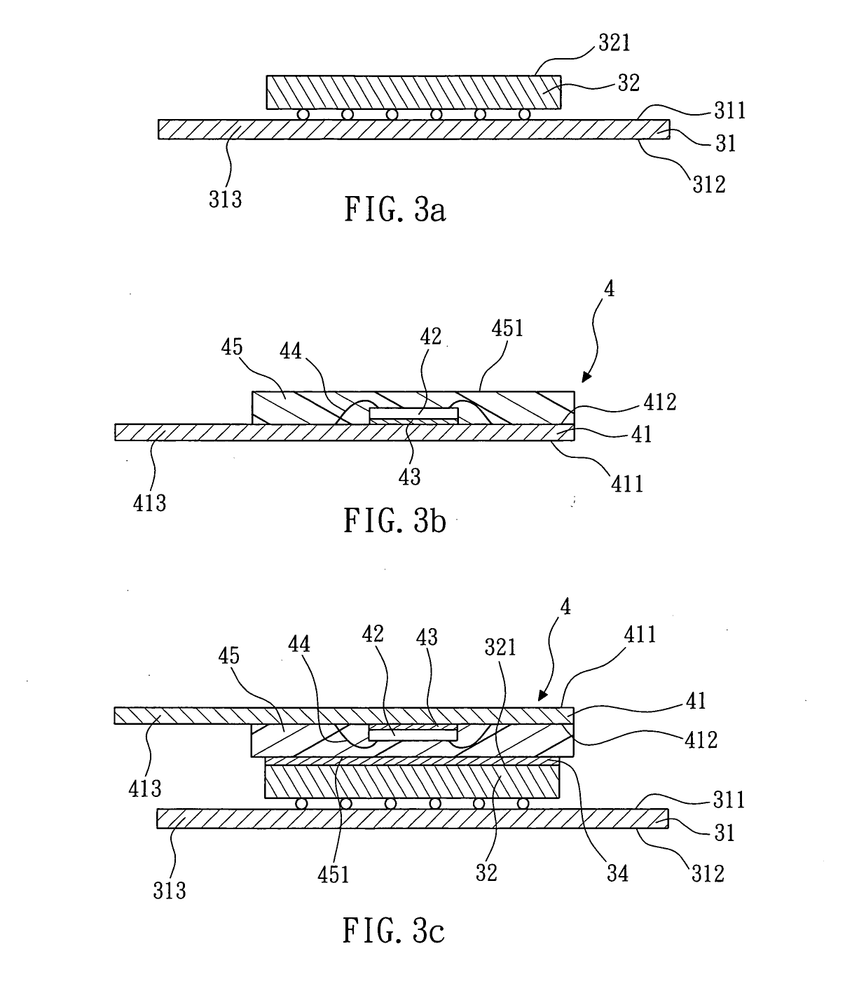

Referring to FIGS. 3a -3f, schematic views of a manufacturing process of the first embodiment in FIG. 2 are illustrated. First, referring to FIG. 3a, a first substrate 31 is provided. The first substrate 31 includes a first surface 311, a second surface 312, and a first connection end 313. In the embodiment, the first surface 311 of the first connection end 313 of the first substrate 31 has a plurality of first contacts (not shown) thereon. Then, a first chip 32 is attached to the first surface 311 of the first substrate 31 by flip-chip bonding. The first chip 32 has a first surface 321.

Next, referring to FIG. 3b, a sub-package 4 is provided. The sub-package 4 is tested and confirmed to be a Good Die, before going through the sequential packaging process. In the embodiment, the sub-package 4 comprises a second substrate 41, a second chip 42, a second adhesive 43, a plurality of second connecting wires 44, and a second molding compound 45. The second substrate 41 is a flexible substrate, and has a first surface 411, a second surface 412, and a second connection end 413. In the embodiment, the second surface 412 of the second connection end 413 of the second substrate 41 has a plurality of second contacts (not shown) thereon. The second chip 42 is attached to the second surface 412 of the second substrate 41 by the second adhesive 43. The second connecting wires 44 are used for electrically connecting the second chip 42 and the second surface 412 of the second substrate 41. The second molding compound 45 encloses a part of the second chip 42, the second connecting wires 44, and a part of the second surface 412 of the second substrate 41. The second molding compound 45 has a second surface 451.

Then, referring to FIG. 3c, the sub-package 4 is stacked on the first surface 321 of the first chip 32 after being reversed by 180 degrees, and the second surface 451 of the second molding compound 45 is attached to the first surface 321 of the first chip 32 by a first adhesive 34.

Then, referring to FIG. 3d, the second connection end 413 of the second substrate 41 is directly connected to the first surface 311 of the first substrate 31 by hot pressing, such that the first contacts and the second contacts are electrically connected.

Then, referring to FIG. 3e, a first molding compound 35 is formed to enclose the first chip 32, the sub-package 4, and a part of the first surface 311 of the first substrate 31.

Then, referring to FIG. 3f, a plurality of solder balls 36 are formed on the second surface 312 of the first substrate 31, for connecting an external device.

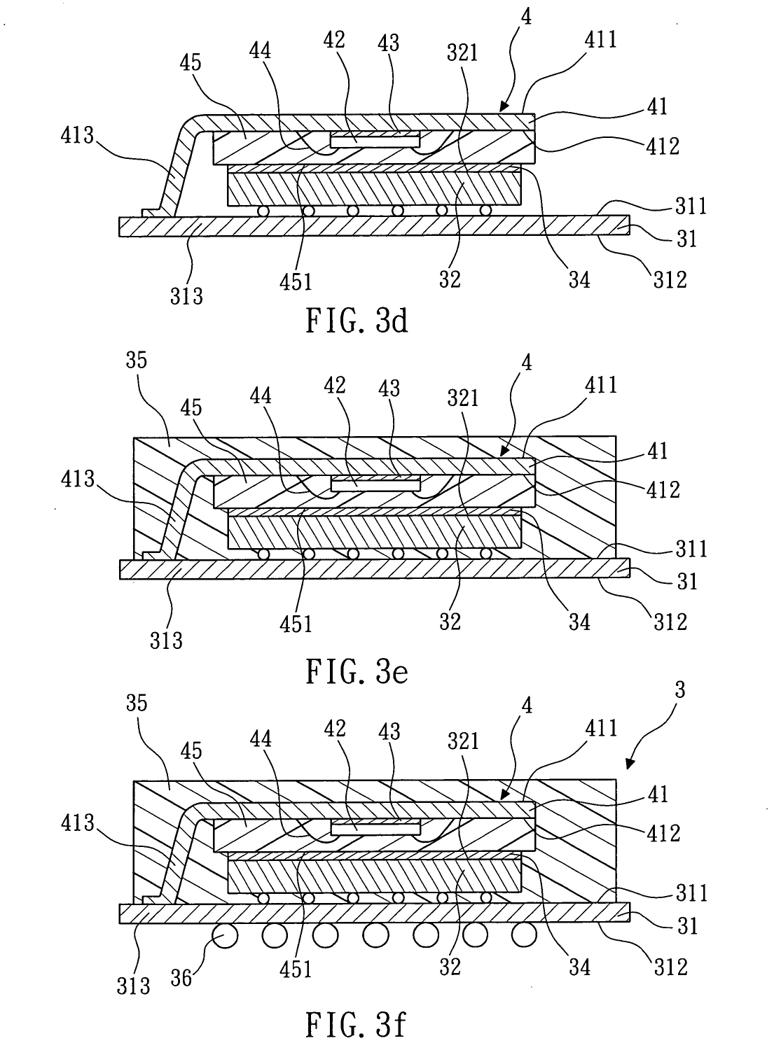

Referring to FIG. 4, a schematic sectional view of the multi-chip package structure according to a second embodiment of the present invention is shown. The multi-chip package structure 3A of the embodiment is substantially the same as the multi-chip package structure 3 of the first embodiment, except that the multi-chip package structure 3A of the present embodiment has an additional third chip 37 disposed on the first surface 411 of the second substrate 41 of the sub-package 4. The third chip 37 is electrically connected to the first surface 311 of the first substrate 31 by a plurality of first connecting wires 38. The third chip 37 may be, but is not limited to, a digital chip, an analog chip, an optical chip, a logic chip, a microprocessing chip, or a memory chip.

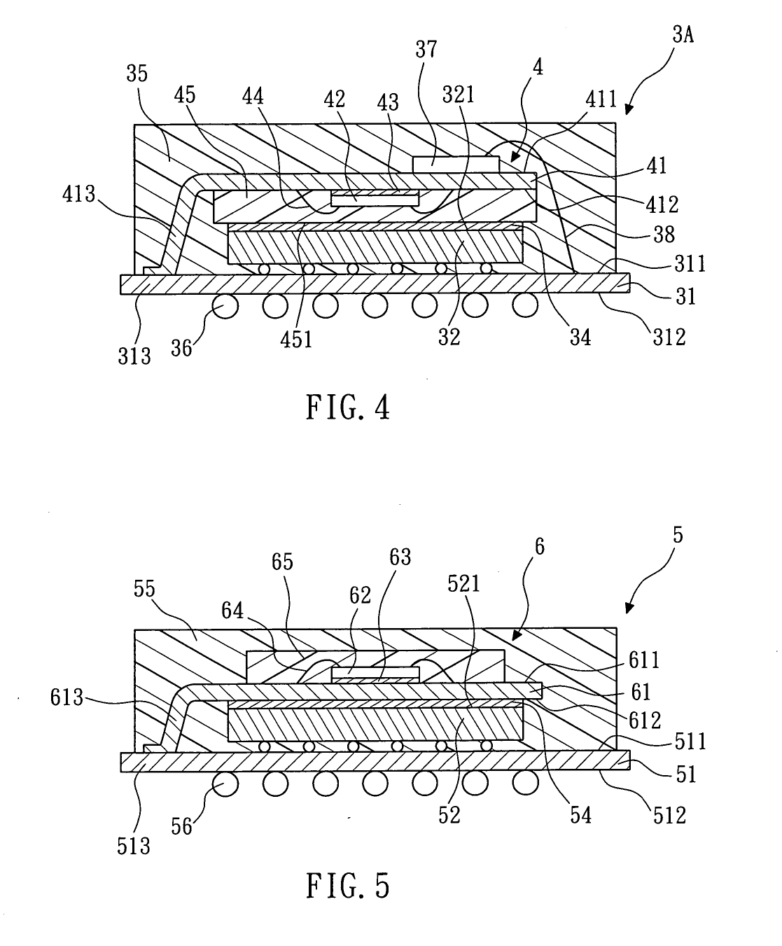

Referring to FIG. 5, a schematic sectional view of the multi-chip package structure according to a third embodiment of the present invention is shown. The multi-chip package structure 5 comprises a first substrate 51, a first chip 52, a sub-package 6, a first adhesive 54, a first molding compound 55, and a plurality of solder balls 56. The first substrate 51 has a first surface 511 (upper surface), a second surface 512 (lower surface), and a first connection end 513. The first chip 52 is attached to the first surface 511 of the first substrate 51 by flip-chip bonding. The first chip 52 has a first surface 521 (upper surface). The first chip 52 may be, but is not limited to, a digital chip, an analog chip, an optical chip, a logic chip, a microprocessing chip, or a memory chip.

The sub-package 6 comprises a second substrate 61, a second chip 62, a second adhesive 63, a plurality of second connecting wires 64, and a second molding compound 65. The second substrate 61 has a first surface 611 (upper surface), a second surface 612 (lower surface), and a second connection end 613. The second chip 62 is attached to the first surface 611 of the second substrate 61 by the second adhesive 63. The second chip 62 may be, but is not limited to, a digital chip, an analog chip, an optical chip, a logic chip, a microprocessing chip, or a memory chip. The second connecting wires 64 are used for electrically connecting the second chip 62 to the first surface 611 of the second substrate 61. The second molding compound 65 encloses the part of the second chip 62, the second connecting wires 64, and a part of the first surface 611 of the second substrate 61.

The sub-package 6 is stacked on the first surface 521 of the first chip 52, and the second surface 612 of the second substrate 61 is attached to the first surface 521 of the first chip 52 by the first adhesive 54. Moreover, the second substrate 61 is a flexible substrate, and the second connection end 613 is connected to the first surface 511 of the first connection end 513 of the first substrate 51. In the embodiment, the first surface 511 of the first connection end 513 of the first substrate 51 has a plurality of first contacts (not shown) thereon, and the second surface 612 of the second connection end 613 of the second substrate 61 has a plurality of second contacts (not shown) thereon. After the second surface 612 of the second connection end 613 of the second substrate 61 directly contacts the first surface 511 of the first connection end 513 of the first substrate 51, the first contacts and the second contacts are electrically connected by hot pressing.

The first molding compound 55 encloses the first chip 52, the sub-package 6, and a part of the first surface 511 of the first substrate 51. The solder balls 56 are formed on the second surface 512 of the first substrate 51, for connecting an external device.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

1. A multi-chip package structure, comprising:
a first substrate having a first surface and a second surface;
a first chip attached to the first surface of the first substrate by flip-chip bonding;
a sub-package stacked on the first chip, the sub-package comprising
a second substrate having a first surface and a second surface, the second substrate being a flexible substrate and connected to the first surface of the first substrate directly,
a second chip electrically connected to the second substrate, and
a second molding compound enclosing the second chip and a part of the second substrate; and
a first molding compound enclosing the first chip, the sub-package, and a part of the first surface of the first substrate.

2. The package structure as claimed in claim 1, wherein the sub-package further comprises a first adhesive for attaching the second chip to the second surface of the second substrate.

3. The package structure as claimed in claim 2, wherein the first chip has a first surface, the second molding compound has a second surface, and the second surface of the second molding compound is attached to the first surface of the first chip by a second adhesive.

4. The package structure as claimed in claim 1, wherein the sub-package further comprises a first adhesive for attaching the second chip to the first surface of the second substrate.

5. The package structure as claimed in claim 4, wherein the first chip has a first surface, and the second surface of the second substrate is attached to the first surface of the first chip by a second adhesive.

6. The package structure as claimed in claim 1, wherein the sub-package further comprises a plurality of first connecting wires for electrically connecting the second substrate and the second chip.

7. The package structure as claimed in claim 1, wherein the first surface of the first substrate has a plurality of first contacts, the second surface of the second substrate has a plurality of second contacts, and the second surface of the second substrate directly contacts the first surface of the first substrate, such that the first contacts and the second contacts are electrically connected.

8. The package structure as claimed in claim 1, wherein the second substrate is electrically connected to the first surface of the first substrate by hot pressing.

9. The package structure as claimed in claim 1, further comprising a third chip disposed on the first surface of the second substrate, the third chip being electrically connected to the first substrate by a plurality of first connecting wires.

10. The package structure as claimed in claim 1, further comprising a plurality of solder balls formed on the second surface of the first substrate.

11. The package structure as claimed in claim 1, wherein the first chip is selected from a group consisting of a digital chip, an analog chip, an optical chip, a logic chip, a microprocessing chip, and a memory chip.

12. The package structure as claimed in claim 1, wherein the second chip is selected from a group consisting of a digital chip, an analog chip, an optical chip, a logic chip, a microprocessing chip, and a memory chip.
